(19) United States
(12) Patent Application Publication
(10) Pub. No.: US 2011/0180896 A1
(43) Pub. Date: Jul. 28, 2011

(54) METHOD OF PRODUCING BONDED WAFER STRUCTURE WITH BURIED OXIDE/NITRIDE LAYERS

(75) Inventors: Gerd Pfeiffer, Hopewell Junction, NY (US); Haizhou Yin, Poughkeepsie, NY (US); Edmund J. Sprogis, Essex Junction, VT (US); Subramanian Iyer, Hopewell Junction, NY (US); Zhibin Ren, Hopewell Junction, NY (US); Dae-Gyu Park, Hopewell Junction, NY (US); Oleg Gluschenkov, Hopewell Junction, NY (US)

(73) Assignee: INTERNATIONAL BUSINESS MACHINES CORPORATION, Armonk, NY (US)

(21) Appl. No.: 12/692,983

(22) Filed: Jan. 25, 2010

(51) Int. Cl. H01L 29/06; H01L 21/762

(52) U.S. Cl. 257/506; 438/459; 257/E21.567; 257/E29.018

(57) ABSTRACT

A method of forming a bonded wafer structure includes providing a first semiconductor wafer substrate having a first silicon oxide layer at the top surface of the first semiconductor wafer substrate; providing a second semiconductor wafer substrate; forming a second silicon oxide layer on the second semiconductor wafer substrate; forming a silicon nitride layer on the second silicon oxide layer; and bringing the first silicon oxide layer of the first semiconductor wafer substrate into physical contact with the silicon nitride layer of the second semiconductor wafer substrate to form a bonded interface between the first silicon oxide layer and the silicon nitride layer. Alternatively, a third silicon oxide layer may be formed on the silicon nitride layer before bonding. A bonded interface is then formed between the first and third silicon oxide layers. A bonded wafer structure formed by such a method is also provided.

### FIELD OF THE INVENTION

The present invention relates to the field of wafer bonding. More particularly, the invention concerns a method of producing a bonded wafer with buried oxide/nitride layers.

### BACKGROUND OF THE INVENTION

Advanced designs in semiconductor industry increasingly require a multiple wafer integration strategy where a plurality of wafers are bonded together to form a bonded wafer structure. For example, a semiconductor-on-insulator (SOI) substrate may be formed by a wafer bonding process in which two semiconductor wafers, one of which includes a layer of insulating material at the bonding surface, are brought into intimate contact with each other. The bonded wafer is then ground mechanically and polished to form a SOI layer. Alternatively, the wafer bonding process may utilize a layer transfer (for example SMARTCUT or Silicon Gensis) process in which ions of hydrogen or a noble gas or the like are implanted into a first wafer and after bonding the first wafer to a second wafer, a portion of the first wafer including the implanted species is separated from the rest of the bonded wafer structure.

A number of bonding techniques are known to create strong and reliable bonds between wafers. Fusion bonding (or direct bonding) is a process where two wafers with clean and flat surfaces are covalently bonded through the application of pressure and heat. In order to achieve a bond of satisfactory strength, the wafers must be annealed at temperatures generally greater than 700° C. Anodic boning process involves bonding a silicon surface with a borosilicate glass surface through the application of strong electric fields and heat. Adhesive wafer bonding utilizes intermediate polymer adhesives to hold the surfaces together. The main advantages of adhesive wafer bonding include the insensitivity to surface topography, the low bonding temperatures, and the ability to join different types of wafers. However, the bond strengths of adhesive wafer bonding are typically lower than those of either fusion or anodic bonding. In addition, the bonding adhesives typically cannot withstand high temperatures needed for standard complementary metal-oxide-semiconductor (CMOS) processing.

Bonded wafer structures with a layer stack combination of silicon-silicon dioxide-silicon nitride are needed for advanced layer transfer applications. In order for these structures to be useful, the bond needs to be of satisfactory strength and the bonded interface needs to be of high quality (no bonding defects and non-bonded areas). In addition, the bonding process needs to be compatible with CMOS processing. However, it is difficult to bond a silicon nitride layer to a silicon layer using standard wafer bonding techniques. Due to the hydrophobic nature of the silicon nitride surface, bonding defects and non-bonded areas often exist at the interface between the silicon nitride and the silicon layers.

### SUMMARY OF THE INVENTION

The present invention provides a method of forming a bonded wafer structure with buried oxide/nitride layers. In this method, the bonding surfaces are either a silicon nitride layer and a silicon oxide layer or two silicon oxide layers. Since the bonding is not between a silicon nitride layer and a silicon layer, standard wafer bonding techniques such as fusion bonding may be used to facilitate the bonding process. In addition, the bond has satisfactory strength and is free of common bonding defects existing at a bonded interface between a silicon nitride layer and a silicon layer. The present invention also provides a bonded wafer structure formed by such a method.

A first embodiment introduces a method of forming a bonded wafer structure. The method includes the steps of providing a first semiconductor wafer substrate having a first silicon oxide layer at the top surface of the first semiconductor wafer substrate; providing a second semiconductor wafer substrate; forming a second silicon oxide layer on the second semiconductor wafer substrate; forming a silicon nitride layer on the second silicon oxide layer; and bringing the first silicon oxide layer of the first semiconductor wafer substrate into physical contact with the silicon nitride layer of the second semiconductor wafer substrate to form a bonded interface between the first silicon oxide layer and the silicon nitride layer.

A second embodiment introduces a method of forming a bonded wafer structure. The method includes the steps of providing a first semiconductor wafer substrate having a first silicon oxide layer at the top surface of the first semiconductor wafer substrate; providing a second semiconductor wafer substrate; forming a second silicon oxide layer on the second semiconductor wafer substrate; forming a silicon nitride layer on the second silicon oxide layer; forming a third silicon oxide layer on the silicon nitride layer; and bringing the first silicon oxide layer of the first semiconductor wafer substrate into physical contact with the third silicon oxide layer of the second semiconductor wafer substrate to form a bonded interface between the first and the third silicon oxide layers.

A third embodiment introduces a bonded wafer structure including a first semiconductor wafer substrate; a first silicon oxide layer on the first semiconductor wafer substrate; a silicon nitride layer on the first silicon oxide layer; a second silicon oxide layer on the silicon nitride layer; and a second semiconductor wafer substrate on the second silicon oxide layer, wherein the first silicon oxide layer forms a bonded interface with the silicon nitride layer.

A fourth embodiment introduces a bonded wafer structure including a first semiconductor wafer substrate; a first silicon oxide layer on the first semiconductor wafer substrate; a third silicon oxide layer on first silicon oxide layer; a silicon nitride layer on the third silicon oxide layer; a second silicon oxide layer on the silicon nitride layer; and a second semiconductor wafer substrate on the second silicon oxide layer, wherein the first silicon oxide layer forms a bonded interface with the third silicon oxide layer.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart illustrating a method of forming a bonded wafer structure, in accordance with one embodiment of the present invention.

FIGS. 2-7 are cross-sectional views that illustrate exemplary processing steps following the process flow of FIG. 1.

FIGS. 8-10 are cross-sectional views that illustrate exemplary alternative processing steps that can be used in the present invention.

It will be appreciated that for simplicity and clarity of illustration, elements shown in the drawings have not necessarily been drawn to scale. For example, the dimensions of some of the elements may be exaggerated relative to other elements for purpose of clarity.

### DETAILED DESCRIPTION OF THE INVENTION

The present invention will now be described more fully hereinafter with reference to the accompanying drawings in which preferred embodiments of the invention are shown. This invention may, however, be embodied in many different forms and should not be construed as limited to the illustrated embodiments set forth herein. Rather, these embodiments are provided so that this disclosure will be thorough and complete, and will fully convey the scope of the invention to those skilled in the art. Like numerals refer to like features throughout.

It will be understood that when an element, such as a layer, is referred to as being “on” or “over” another element, it can be directly on the other element or intervening elements may also be present. In contrast, when an element is referred to as being “directly on” or “directly over” another element, there are no intervening elements present. Throughout the present application the term “bottom wafer” or “bottom wafer substrate” are used to denote a semiconductor wafer that is located beneath the bonded interface, while the term “top wafer” or “top wafer substrate” are used to denote a semiconductor wafer that is located above the bonded interface in the bonded wafer structure.

As stated above, the present invention provides a method of forming a bonded wafer structure with buried oxide/nitride layers. In this method, a bottom wafer having a silicon oxide layer at its bonding surface is bonded to a top wafer having a silicon nitride layer or a silicon oxide layer at its bonding surface. This method avoids bonding directly between a silicon nitride layer and a silicon layer. As a result, standard wafer bonding techniques such as fusion bonding may be used to facilitate the bonding process. In addition, the bonded interface has satisfactory strength and is free of common bonding defects existing at a bonded interface between a silicon nitride layer and a silicon layer.

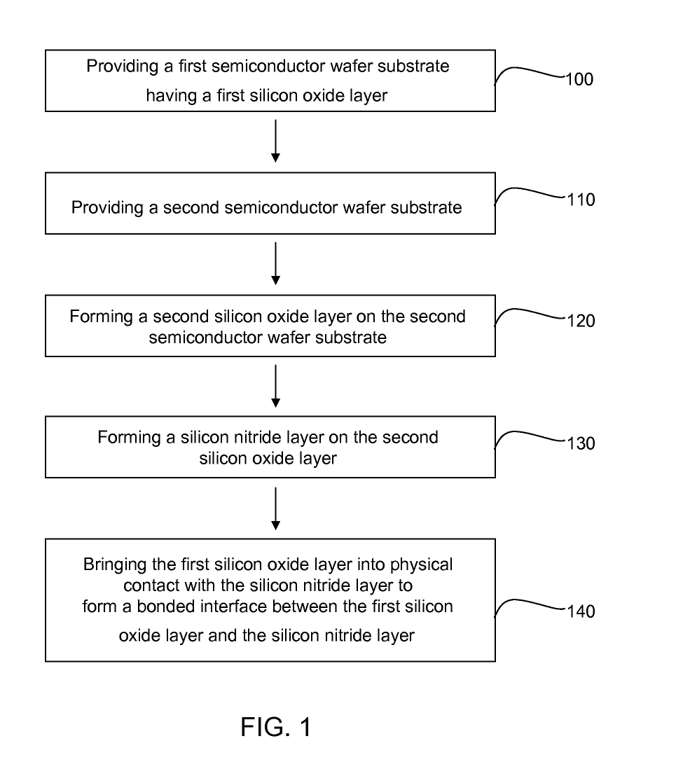

Reference is first made to FIG. 1 which is a flow chart illustrating a method of forming a bonded wafer structure according to one embodiment of the present invention.

In Step 100, a first semiconductor wafer substrate having a first silicon oxide layer is provided. The first silicon oxide layer may be formed by thermal oxidation or chemical deposition. The first semiconductor wafer substrate is preferably the bottom wafer for the bonded wafer structure.

In Step 110, a second semiconductor wafer substrate is provided. The second semiconductor wafer substrate is preferably the top wafer for the bonded wafer structure.

The first and the second semiconductor wafer substrates may comprise the same or different semiconductor material. Semiconductor materials suitable as the first and the second semiconductor wafer substrates include, but are not limited to, Si, SiGe, SiGeC, SiC, Ge alloys, GaAs, InAs, InP or other group III/V or II/VI semiconductor materials. In addition to these listed types of semiconducting materials, the present invention also contemplates cases in which the wafer substrate is a layered semiconductor such as, for example, Si/SiGe, Si/SiC, silicon-on-insulator (SOI) or silicon germanium-on-insulator (SiGeOI). One or more semiconductor devices such as, for example, complementary metal oxide semiconductor (CMOS) devices may be fabricated on the first and the second semiconductor wafer substrates.

Preferably, the first and the second semiconductor wafer substrates are comprised of a silicon-containing semiconductor material such as, for example, Si, SiGe, SiGeC or multilayers thereof. More preferably, the first and the second semiconductor wafer substrates are both comprised of silicon.

In Step 120, a second silicon oxide layer is formed on the second semiconductor wafer substrate. Preferably, the second silicon oxide layer is formed thermally in an oxidizing atmosphere at an elevated temperature. A typical temperature for the oxidation process is from about 800° C. to about 1200° C. The oxidation process is preferably carried out at an oxygen partial pressure of 0.2-1.0 atm (20−100 kPa).

In Step 130, a silicon nitride layer is formed on the second silicon oxide layer. The silicon nitride layer may be formed by a thermal deposition, a nitridation or a nitrogen implant process. The thermal deposition process includes Chemical Vapor Deposition (CVD) and Low Pressure Chemical Vapor Deposition (LPCVD). The nitridation process includes Slot Plane Antenna (SPA) which uses a plasma source of Radial Line Slot Antenna (RLSA) and Decoupled Plasma Nitridation (DPN). The nitrogen implant process includes an ion-cluster beam deposition process using N₂, N* (activated N species created during plasma), or N (atomic nitrogen) sources.

In Step 140, the first silicon oxide layer of the first semiconductor wafer substrate is brought into physical contact with the silicon nitride layer of the second semiconductor wafer substrate to form a bonded interface between the first silicon oxide layer and the silicon nitride layer. This process is typically carried out at ambient temperature and pressure. However, other conditions can also be used.

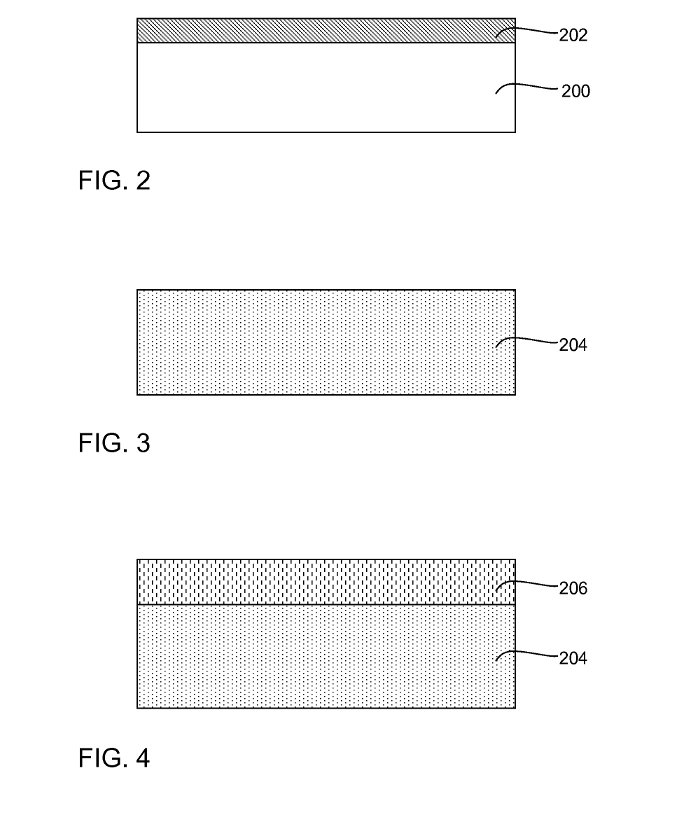

A specific example resulting from the process steps of FIG. 1 is depicted in FIGS. 2-8. Referring now to FIG. 2, a first semiconductor wafer substrate 200 having a first silicon oxide layer 202 on its top surface is provided, such as described in Step 100 above. The first semiconductor wafer substrate 200 is preferably comprised of silicon. More preferably, the first semiconductor wafer substrate 200 is a standard silicon wafer with a thickness ranging from about 400 μm to about 800 μm. The first silicon oxide layer 202 preferably has a thickness from about 3 nm to about 250 nm, more preferably from about 5 nm to about 150 nm. The first semiconductor wafer substrate 200 is the bottom wafer for the bonded wafer structure.

Referring now to FIG. 3, a second semiconductor wafer substrate 204 is provided, such as described in Step 110 above. The second semiconductor wafer substrate 204 is preferably comprised of silicon. More preferably, the second semiconductor wafer substrate 204 is a standard silicon wafer with a thickness ranging from about 400 μm to about 800 μm. The second semiconductor wafer substrate 204 is the top wafer for the bonded wafer structure.

In FIG. 4, a second silicon oxide layer 206 is formed on the second semiconductor wafer substrate 204 by a method such as the one described in Step 120 above. The second silicon oxide layer 206 is preferably a thermal oxide layer. The second silicon oxide layer 206 preferably has a thickness from about 150 nm to about 4000 nm, more preferably from about 400 nm to about 2000 nm.

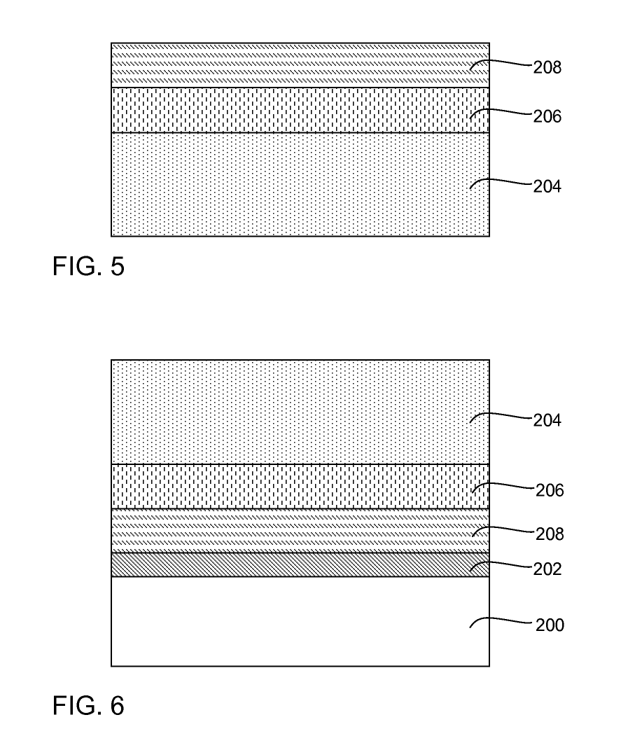

Referring now to FIG. 5, a silicon nitride layer 208 is formed on the second silicon oxide layer 206 by a method such as the one described in Step 130 above. The silicon nitride layer 208 preferably has a thickness from about 10 nm to about 500 nm, more preferably from about 50 nm to about 200 nm.

Optionally, the silicon nitride layer 208 is polished to reduce its surface roughness. The polishing method for silicon nitride is chemical mechanical polishing (CMP) using a combination of polishing slurry and chemicals specific to silicon nitride.

In FIG. 6, the first silicon oxide layer 202 is brought into physical contact with the silicon nitride layer 208 by a method such as the one described in Step 140 above. A bonded interface is formed between the first silicon oxide layer 202 and the silicon nitride layer 208. As shown in FIG. 6, in the bonded wafer structure, the second semiconductor wafer substrate 204, the second silicon oxide layer 206 and the silicon nitride layer 208 are all above the bonded interface, while the first silicon oxide layer 202 and the first semiconductor wafer substrate 200 are underneath the bonded interface.

Since the bonded interface is below the silicon nitride layer 208 which acts as a shield to the bonded interface, any subsequent patterning processes (e.g., RIE etching and/or cleaning processes) in the top active layers including the second semiconductor wafer substrate 204 and the second silicon oxide layer 206 do not erode the bonded interface. In addition, because the top active layers are separated from the bonded interface by the silicon nitride layer 208, the electrical properties of the top active layers are not affected by the bonded interface.

After bonding, the bonded wafer structure in FIG. 6 may be further annealed to strengthen the bond at the interface. Preferably, the annealing is performed at a temperature above 1000° C. More preferably, the annealing is performed at a temperature from about 1100° C. to about 1200° C. A typical annealing time is from about 15 minutes to about 180 minutes.

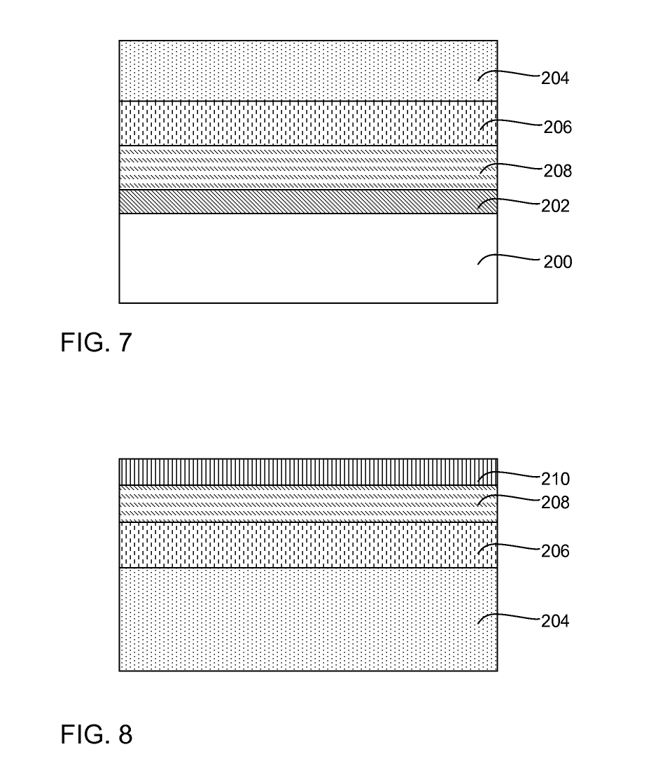

The bonded wafer structure shown in FIG. 6 may be subjected to a grinding and polishing process to reduce the thickness of the second semiconductor wafer substrate 204 (FIG. 7). The preferred thickness of the second semiconductor wafer substrate 204 after the grinding and polishing process is from about 1 m to about 200 m.

Alternatively, after the silicon nitride layer 208 is formed, a third silicon oxide layer 210 may be formed on the silicon nitride layer 208 (FIG. 8). The third silicon oxide layer 210 may be formed by thermal deposition such as, for example, CVD, or alternatively, partial thermal oxidation of the silicon nitride layer. The third silicon oxide layer 210 preferably has a thickness from about 2 nm to about 500 nm, more preferably from about 5 nm to about 100 nm. In this scheme, the third silicon oxide layer 210 replaces the silicon nitride layer 208 as the bonding surface for the top wafer.

Optionally, the third silicon oxide layer 210 is polished to reduce its surface roughness. A CMP process using a combination of polishing slurry and chemicals specific to silicon oxide is used to polish the third silicon oxide layer 210.

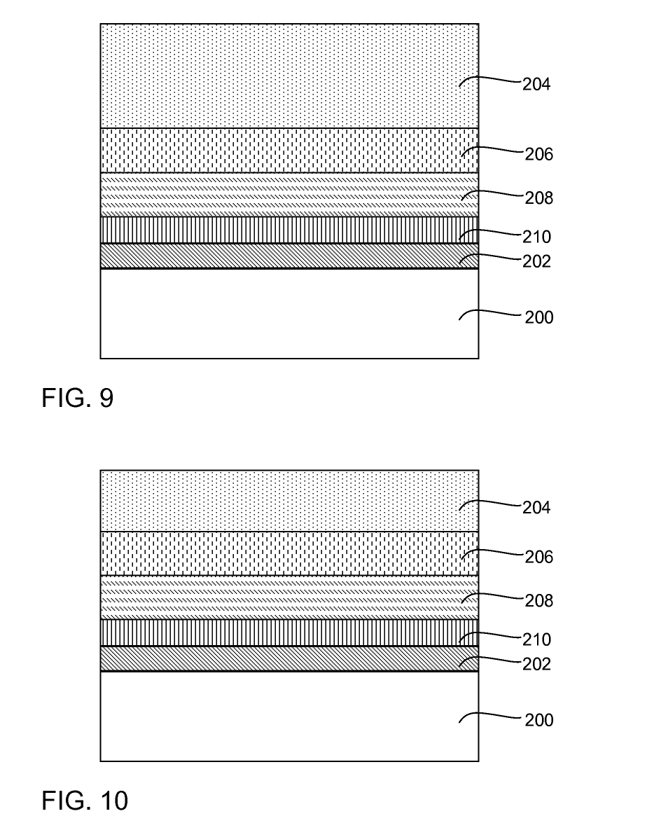

Referring now to FIG. 9, the first silicon oxide layer 202 is brought into physical contact with the third silicon oxide layer 210. This process is typically carried out at ambient temperature and pressure. However, other conditions can also be used. A bonded interface is formed between the first silicon oxide layer 202 and the third silicon oxide layer 210. As shown in FIG. 9, in the bonded wafer structure, the second semiconductor wafer substrate 204, the second silicon oxide layer 206, the silicon nitride layer 208 and the third silicon oxide layer 210 are all above the bonded interface, while the first silicon oxide layer 202 and the first semiconductor wafer substrate 200 are underneath the bonded interface.

Similar to the bonded wafer structure in FIG. 6, the bonded wafer structure in FIG. 9 has a bonded interface below the silicon nitride layer 208 and the third silicon oxide layer 210 which act as a shield to the bonded interface. As a result, any subsequent patterning processes (e.g., RIE etching and/or cleaning processes) in the top active layers including the second semiconductor wafer substrate 204 and the second silicon oxide layer 206 do not erode the bonded interface. In addition, since the top active layers are separated from the bonded interface by the silicon nitride layer 208 and the third silicon oxide layer 210, the electrical properties of the top active layers are not affected by the bonded interface.

After bonding, the bonded wafer structure in FIG. 9 may be further annealed to strengthen the bond at the interface. Preferably, the annealing is performed at a temperature above 1000° C. More preferably, the annealing is performed at a temperature from about 1100° C. to about 1200° C. A typical annealing time is from about 15 minutes to about 180 minutes.

The bonded wafer structure shown in FIG. 9 may be subjected to a grinding and polishing process to reduce the thickness of the second semiconductor wafer substrate 204 (FIG. 10). The preferred thickness of the second semiconductor wafer substrate 204 after the grinding and polishing process is from about 1 m to about 200 m.

While the present invention has been particularly shown and described with respect to preferred embodiments, it will be understood by those skilled in the art that the foregoing and other changes in forms and details may be made without departing from the spirit and scope of the invention. It is therefore intended that the present invention not be limited to the exact forms and details described and illustrated but fall within the scope of the appended claims.

What is claimed is:

1. A method of forming a bonded wafer structure comprising:
providing a first semiconductor wafer substrate having a first silicon oxide layer at the top surface of the first semiconductor wafer substrate;
providing a second semiconductor wafer substrate;
forming a second silicon oxide layer on the second semiconductor wafer substrate;
forming a silicon nitride layer on the second silicon oxide layer; and
bringing the first silicon oxide layer of the first semiconductor wafer substrate into physical contact with the silicon nitride layer of the second semiconductor wafer substrate to form a bonded interface between the first silicon oxide layer and the silicon nitride layer.

2. The method of claim 1, further comprising the step of annealing the bonded first and second semiconductor wafer substrates at a temperature greater than about 1000° C.

3. The method of claim 2, wherein the annealing is performed at a temperature from about 1100° C. to about 1200° C.

4. The method of claim 1, further comprising the step of polishing the silicon nitride layer to reduce its surface roughness before bringing it into physical contact with the first silicon oxide layer.

5. The method of claim 1, wherein the second silicon oxide layer is formed thermally.

6. The method of claim 5, wherein the second silicon oxide has a thickness from about 150 nm to about 4000 nm.

7. The method of claim 1, wherein the silicon nitride layer is formed by a thermal deposition, a nitridation or a nitrogen implant process.

8. The method of claim 1, wherein the first silicon oxide layer has a thickness from about 3 nm to about 250 nm.

9. The method of claim 1, further comprising grinding and polishing the second semiconductor wafer substrate to reduce the thickness of the second semiconductor wafer substrate.

10. A method of forming a bonded wafer structure comprising:
providing a first semiconductor wafer substrate having a first silicon oxide layer at the top surface of the first semiconductor wafer substrate;
providing a second semiconductor wafer substrate;
forming a second silicon oxide layer on the second semiconductor wafer substrate;
forming a silicon nitride layer on the second silicon oxide layer;
forming a third silicon oxide layer on the silicon nitride layer; and
bringing the first silicon oxide layer of the first semiconductor wafer substrate into physical contact with the third silicon oxide layer of the second semiconductor wafer substrate to form a bonded interface between the first and the third silicon oxide layers.

11. The method of claim 10, further comprising the step of annealing the bonded first and second semiconductor wafer substrates at a temperature greater than about 1000° C.

12. The method of claim 11, wherein the annealing is performed at a temperature from about 1100° C. to about 1200° C.

13. The method of claim 10, further comprising the step of polishing the third silicon oxide layer to reduce its surface roughness before bringing it into physical contact with the first silicon oxide layer.

14. The method of claim 10, wherein the second silicon oxide layer is formed thermally.

15. The method of claim 14, wherein the second silicon oxide has a thickness from about 150 nm to about 4000 nm.

16. The method of claim 10, wherein the silicon nitride layer is formed by a thermal deposition, a nitridation or a nitrogen implant process.

17. The method of claim 10, wherein the first silicon oxide layer has a thickness from about 3 nm to about 250 nm.

18. The method of claim 10, further comprising grinding and polishing the second semiconductor wafer substrate to reduce the thickness of the second semiconductor wafer substrate.

19. A bonded wafer structure comprising:
a first semiconductor wafer substrate;
a first silicon oxide layer on the first semiconductor wafer substrate;
a silicon nitride layer on the first silicon oxide layer;
a second silicon oxide layer on the silicon nitride layer; and
a second semiconductor wafer substrate on the second silicon oxide layer, wherein the first silicon oxide layer forms a bonded interface with the silicon nitride layer.

20. The bonded wafer structure of claim 19, the second silicon oxide layer is a thermal oxide.

21. The bonded wafer structure of claim 20, wherein the second silicon oxide has a thickness from about 150 nm to about 4000 nm.

22. The bonded wafer structure of claim 19, wherein the silicon nitride layer is formed by a thermal deposition, a nitridation or a nitrogen implant process.

23. The bonded wafer structure of claim 19, wherein the first silicon oxide layer has a thickness from about 3 nm to about 250 nm.

24. The bonded wafer structure of claim 19, wherein the second semiconductor wafer substrate has a thickness from about 1 m to about 200 m.

25. A bonded wafer structure comprising:
a first semiconductor wafer substrate;
a first silicon oxide layer on the first semiconductor wafer substrate;
a third silicon oxide layer on first silicon oxide layer;
a silicon nitride layer on the third silicon oxide layer;
a second silicon oxide layer on the silicon nitride layer; and
a second semiconductor wafer substrate on the second silicon oxide layer, wherein the first silicon oxide layer forms a bonded interface with the third silicon oxide layer.

26. The bonded wafer structure of claim 25, the second silicon oxide layer is a thermal oxide.

27. The bonded wafer structure of claim 26, wherein the second silicon oxide has a thickness from about 150 nm to about 4000 nm.

28. The bonded wafer structure of claim 25, wherein the silicon nitride layer is formed by a thermal deposition, a nitridation or a nitrogen implant process.

29. The bonded wafer structure of claim 25, wherein the first silicon oxide layer has a thickness from about 3 nm to about 250 nm.

30. The bonded wafer structure of claim 25, wherein the second semiconductor wafer substrate has a thickness from about 1 m to about 200 m.
